(19) United States
(12) Patent Application Publication
(10) Pub. No.: US 2026/0050731 A1
(43) Pub. Date: Feb. 19, 2026

(54) MEMORY WITH HARDWARE FOR VERIFICATION OF LAYOUT

(71) Applicant: QUALCOMM Incorporated, San Diego, CA (US)

(72) Inventors: Channappa DESAI, Haveri (IN); Sunil SHARMA, Bangalore (IN); Prabaharan BALU, Bangalore (IN); Varun VIBHAKARA, Bangalore (IN); Debarghya DUTTA, KOLKATA (IN)

(21) Appl. No.: 18/808,402

(22) Filed: Aug. 19, 2024

(51) Int. Cl. G06F 30/398; G06F 30/392; G11C 16/04

(52) U.S. Cl. CPC G06F 30/398; G06F 30/392; G11C 16/0483

(57) ABSTRACT

A memory is provided with a stack of word line transistors for verifying a word line order and with a stack of bit line transistors for verifying a bit line order. The stack of word line transistors couple between the output terminals of a row decoder and a plurality of word lines. Similarly, the stack of bit line transistors couple between the output terminals of a column multiplexer and a plurality of bit lines.

### TECHNICAL FIELD

The present application relates generally to memories, and more specifically, to a memory with hardware for verification of the layout.

### BACKGROUND

Embedded memories such as static random-access memory (SRAMs) are a major contributor to the semiconductor die space occupied by a system-on-a-chip (SoC) including the embedded memories. For example, the embedded memories may use as much as 80% or more of the total semiconductor die space for the integrated circuit. The embedded memory performance and power consumption is thus a major factor in the success or failure of a SoC. To construct the embedded memories, a designer may first describe them using a suitable digital representation such as through a hardware description language. The hardware description language representation of the memory is then converted to a layout representation of the memory (e.g., a graphic data system representation) that may be delivered to the semiconductor foundry in what is denoted as a “tapeout.”

Once the integrated circuit is manufactured, its operation is verified through the use of memory built-in self-test (MBIST). As part of this testing, various vectors (patterns of binary ones and zeroes) are written to the embedded memories and then retrieved. Proper operation of MBIST requires each embedded memory to have a known bit line and word line order. But it is cumbersome with modern electronic design and automation tools to verify the word line and bit line ordering in the layout representation of the memory.

### SUMMARY

In accordance with an aspect of the disclosure, a memory is provided that includes: a first word line; a second word line; a row decoder including a first logic gate having a first output terminal coupled to the first word line and a second logic gate having a second output terminal coupled to the second word line; an at least one bank selection transistor having a gate coupled to a node for bank selection signal; a first word line transistor having a first drain/source terminal coupled to the at least one bank selection transistor and having a gate coupled to the first output terminal; and a second word line transistor having a first drain/source terminal coupled to a second drain/source terminal of the first word line transistor and having a gate coupled to the second output terminal.

In accordance with another aspect of the disclosure, a memory is provided that includes: a plurality of bitcells arranged into a plurality of rows of bitcells ranging from a first row of bitcells to a last row of bitcells; a plurality of word lines ranging from a first word line to a last word line, each word line being arranged to couple to a corresponding row of bitcells such that the first word line is coupled to the first row of bitcells, a second word line is coupled to a second row of bitcells, and so on such that the last word line is coupled to the last row of bitcells; a row decoder having a plurality of output terminals ranging from a first output terminal to a last output terminal arranged corresponding to the plurality of word lines such that the first output terminal is coupled to the first word line, a second output terminal is coupled to the second word line, and so on such that the last output terminal is coupled to the last word line; and a plurality of word line transistors coupled in series and ranging from a first word line transistor to a last word line transistor, the plurality of word line transistors being arranged such that a gate of the first word line transistor is coupled to the first output terminal, a gate of a second word line transistor is coupled to the second output terminal; and so on such that a gate of the last word line transistor is coupled to the last output terminal.

Finally, in accordance with another aspect of the disclosure, a memory is provided that includes: an at least one bank selection transistor having a gate coupled to a node for bank selection signal; a first bit line; a second bit line; a column multiplexer including a first column multiplexer transistor having a source coupled to the first bit line and including a second column multiplexer transistor having a source coupled to the second bit line, wherein a node for a first column address signal couples to gate of the first column multiplexer transistor and couples to a gate of the second column multiplexer transistor; a first bit line transistor having a first source/drain terminal coupled to the at least one bank selection transistor and having a gate coupled to the source of the first column multiplexer transistor; and a second bit line transistor having a first source/drain terminal coupled to a second source/drain terminal of the first bit line transistor and having a gate coupled to the source of the second column multiplexer transistor.

These and other advantageous features may be better appreciated through the following detailed description.

### BRIEF DESCRIPTION OF THE DRAWINGS

FIG. 1 illustrates a memory in accordance with an aspect of the disclosure.

FIG. 2 is a more detailed view of a bitcell in the memory of FIG. 1 in accordance with an aspect of the disclosure.

FIG. 3 illustrates a memory with a bit line transistor stack coupled between the column multiplexer and the bit lines to a bank in accordance with an aspect of the disclosure.

FIG. 4 illustrates a memory with a word line transistor stack coupled between the row decoder and the word lines to a bank in accordance with an aspect of the disclosure.

FIG. 5 illustrates a memory including a first bank having bit line transistor stacks and word line transistor stacks coupled through a single bank select transistor and including a second bank having bit line transistors stacks and word line transistor stacks coupled through a pair of bank select transistors in accordance with an aspect of the disclosure.

FIG. 6 is a flowchart for a method of verifying the word line order in a layout representation of a memory in accordance with an aspect of the disclosure.

FIG. 7 illustrates some example electronic systems each including a memory including bit line and word line transistors stacks for verifying the bit line and word line order in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

The following discussion is directed to hardware enhancements in memories that ease the problem of verifying bit line and word line order. These enhancements will be discussed with regard to a static random-access memory (SRAM) implementation but it will be appreciated that other random access memories such as dynamic random-access memory (DRAM) will also benefit from the circuits and techniques disclosed herein. In an SRAM, the bitcells are arranged into rows and columns. Each column includes a pair of bit lines whereas each row includes a word line. Should all the bitcells be arranged into a single array, the length of the bit line and word lines would increase as the number of bitcells increases. Such an increase in bit line and word line length may lead to unacceptably high capacitance for the bit line and word lines. It is thus typical that the bitcells are arranged into banks, with each bank having its own bit lines and word lines.

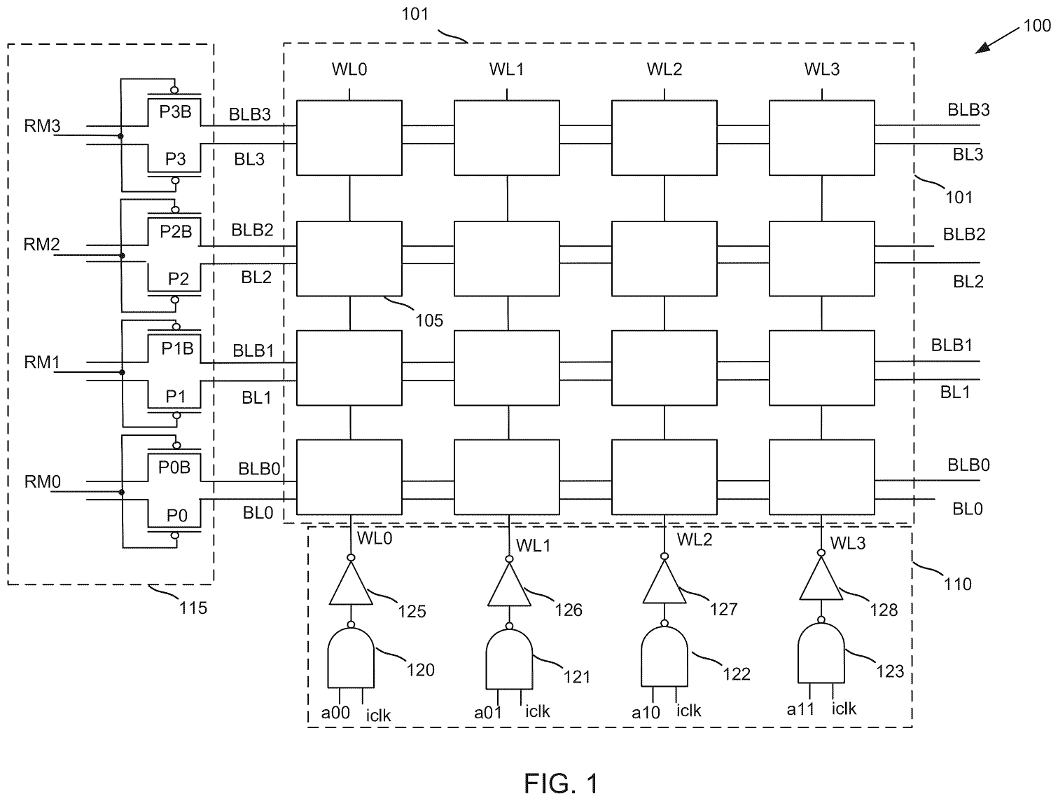

A sub-array 101 of bitcells 105 for a corresponding bank in a memory 100 with a column multiplexer 115 and a portion 110 of a row decoder is shown in FIG. 1. Sub-array 101 is arranged into four columns and four rows with a bitcell 105 at each column and row intersection. A corresponding pair of bit lines traverses each column. For example, a zeroth bit line (BL0) and a complement zeroth bit line (BLB0) extend across a zeroth column. Similarly, a first bit line (BL1) and a complement first bit line (BLB1) traverse a first column. In the same fashion, a second bit line (BL2) and a complement second bit line (BLB2) traverse a second column. Finally, a third bit line (BL3) and a complement third bit line (BLB3) extend across a third column.

During a read or write operation, the column multiplexer 115 selects a pair of bit lines from the four columns. In a read operation, the selected bit lines are then coupled to a sense amplifier (not illustrated) so that a global output bit may be read. Similarly, the column multiplexer 115 selects for a column's pair of bit lines during a write operation so that a global input bit may be written into a selected bitcell 10 through a write driver (not illustrated). Since the column multiplexer 115 structure is generic for either a read or a write operation, the resulting global input or output signal may be referred to as a global input/output (GIO) signal. Memory 100 is a multiplexer 4 (MUX4) memory in that four columns are selected from with respect to the corresponding GIO signal. Other column multiplexing implementations may be used such as MUX2 or MUX8 in alternative implementations.

To select for the zeroth column, the column multiplexer 115 includes a p-type metal-oxide semiconductor (PMOS) column multiplexer transistor P0 having a source coupled to the bit line BL0. Similarly, the column multiplexer 115 includes a PMOS column multiplexer transistor P0B having a source coupled to the complement bit line BLB0. A column address signal RM0 drives the gates of the column multiplexer transistors P0 and P0B to control whether the zeroth column is selected for a read or write operation. Similarly, a PMOS column multiplexer transistor P1 has a source coupled to the bit line BL1 in the first column whereas a PMOS column multiplexer transistor P1B has a source coupled to the complement bit line BLB1. A column address signal RM1 couples to the gates of the column multiplexer transistors P1 and P1B to control whether the first column is selected for by the column multiplexer 115. In addition, a PMOS column multiplexer transistor P2 has a source to the bit line BL2 in the second column whereas a PMOS column multiplexer transistor P2B has a source coupled to the complement bit line BLB2. A column address signal RM2 couples to the gates of the column multiplexer transistors P2 and P2B to control whether the second column is selected for by the column multiplexer 115. Finally, a PMOS column multiplexer transistor P3 has a source coupled to the bit line BL3 in the third column whereas a PMOS column multiplexer transistor P3B has a source coupled to the complement bit line BLB3 in the third column. A column address signal RM3 couples to the gates of the column multiplexer transistors P3 and P3B to control whether the third column is selected for by the column multiplexer 115.

A corresponding word line traverses each row of bitcells 105 ranging from a zeroth word line WL0, a first word line WL1, a second word line WL2, and a third word line WL3. The portion 110 of the row decoder includes logic gates such as a NAND gate and an inverter for each word line. For example, a NAND gate 120 NANDs a predecoded row address signal a00 and a memory clock signal iclk to drive an inverter 125 to control whether the zeroth word line WL0 is asserted. Similarly, a NAND gate 121 NANDs a predecoded row address signal a01 and the memory clock signal iclk to drive an inverter 126 to control whether the first word line WL1 is asserted. In addition, a NAND gate 122 NANDs a predecoded row address signal a10 and the memory clock signal iclk to drive an inverter 127 to control whether the second word line WL2 is asserted. Finally, a NAND gate 123 NANDs a predecoded row address signal a11 and the memory clock signal iclk to drive an inverter 128 to control whether the third word line WL3 is asserted. Other combinations of logic gates may be used in alternative implementations to select for the word lines.

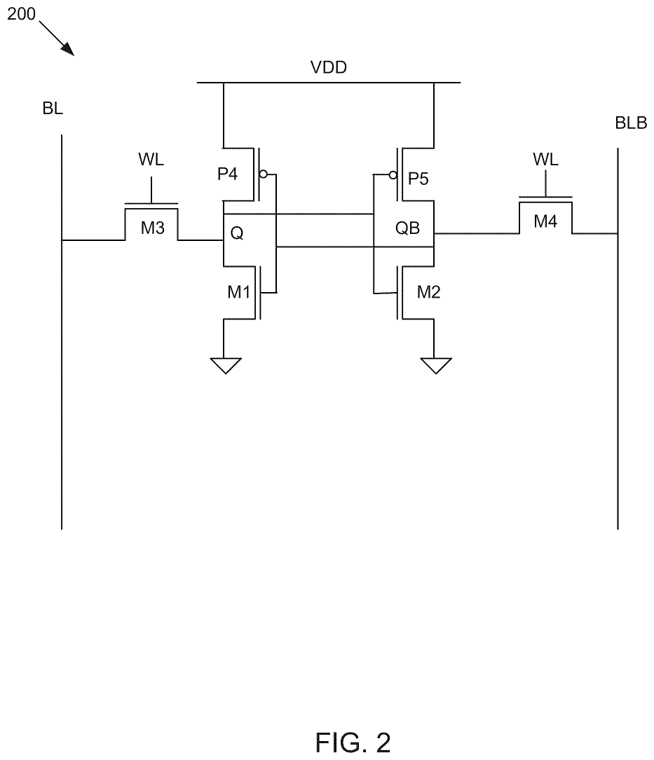

One of the bitcells 105 is shown in more detail in FIG. 2 as a bitcell 200. A bit line BL is a generic representation of one of the bit lines BL0 through BL3 discussed with regard to the memory 100. Similarly, a complement bit line BLB is a generic representation of one of the complement bit lines BLB0 through BLB3. The bitcell 105 includes a first inverter formed by a PMOS transistor P4 having a source coupled to a power supply node for a power supply voltage VDD and a drain coupled to a drain of an n-type metal-oxide semiconductor (NMOS) transistor M1 having a source coupled to ground. The drains of the transistors P4 and M1 support a Q bit signal that may couple through an NMOS access transistor M3 to drive the bit line BL. A word line (WL) that is a generic representation of one of the word lines WL0 through WL3 drives the gate of the access transistor M3 to control whether the Q bit signal may couple to the bit line BL. The Q bit signal also drives a gate of a PMOS transistor P5 and an NMOS transistor M2 forming a second inverter that is cross-coupled with the first inverter. The source of the transistor P5 couples to the power supply node and its drain couples to a drain of the transistor M2 having a source coupled to ground. The drains of the transistors P5 and M2 support a QB complement bit signal that may couple through an NMOS access transistor M4 to drive the complement bit line. The word line WL drives the gate of the access transistor M4 to control whether the QB complement bit signal may couple to the complement bit line BLB.

Note the symmetry of the bitcell 200 with respect to both the bit lines and the word lines. In turn, the column multiplexer 115 is symmetric with respect to each pair of bit lines as each pair of bit lines is selected through a corresponding pair of PMOS column multiplexer transistors. Similarly, the portion 110 of the row decoder is symmetric with respect to each word line since each word line is selected through a serial chain of a NAND gate followed by an inverter. This symmetry introduces an issue with respect to the bit line and word line order. For example, the word lines in the sub-array 101 are arranged in order from the zeroth word line to the third word line. More generally, the corresponding bank will have a plurality n of word lines (n being a plural integer greater than three in this example). The word lines for such a bank will thus be arranged from the zeroth word line to an nth word line. This word line order is important for the memory built-in self-test to correctly identify faults. An analogous order issue exists for the bit line pairs, which in the sub-array 101 are arranged from the zeroth bit line pair to the third bit line pair. More generally, the corresponding bank will have a plurality of m bit line pairs (m being a plural integer greater than three in this example) arranged from the zeroth bit line pair to an mth bit line pair. This bit line order should be maintained for the memory built-in self-test to correctly identify faults. Should the bit line and/or word line order be altered, the memory built-in self-test may not correctly identify the location of the fault in the bank.

With regard to the desired bit line and word line order, a circuit designer may first develop a digital representation of the memory using a suitable hardware description language (HDL). The following discussion will assume that the HDL is MASIS (Memory and SMS Interface) where SMS is an acronym for STAR Memory System, and where STAR is an acronym for Self-Test And Repair). However, it will be appreciated that other types of HDL such as Verilog may be used in alternative implementations. Using MASIS, a circuit designer may specify the desired size of each bank in the memory. Each bank will have a certain number of rows and columns that are arranged in numerical order. But as part of the design process, the memory design is tested in various ways. The software processing of the memory representation may then flip the order of successive bit line pairs or of word lines. For example, referring again to memory 100, suppose that the NAND gate 120 did not process the pre-decoded address signal a00 but instead processed the pre-decoded address signal a01. Similarly, suppose that NAND gate 121 instead processed the pre-decoded address signal a00. In such an implementation, the resulting word order would be WL1, WL0, WL2, and WL3 instead of the desired WL0, WL1, WL2, and WL3 order. A similar problem may occur in the column multiplexer. For example, suppose that the column address signal RM0 drives the gates of the transistors P1 and P1B and that the column address signal RM1 drives the gates of the transistors P0 and P0B. In such an implementation, the zeroth bit line pair BL0 and BLB0 would instead traverse the first column instead of the zeroth column. Similarly, the first bit line pair BL1 and BLB1 would couple across the zeroth column instead of the first column. The resulting reordering of either the word lines and/or the bit lines then undesirably affects the memory built-in self-test as discussed previously.

But detecting the bit line or word line order mismatch is often difficult. With regard to this detection, the MASIS design is converted to a layout representation such as a graphic design system (GDS) representation after a designer is satisfied with the testing of the MASIS design. It is the GDS representation of the memory that is delivered to the semiconductor foundry in what is still denoted as a tapeout. But prior to tapeout, the GDS representation is checked in what is denoted as a layout versus schematic (LVS) process. In an LVS check or test, a netlist is extracted from the layout and compared to the original schematic netlist. Although an LVS process can identify an assortment of errors, it does not currently identify word line or bit line order mismatching. MASIS processing of the layout may identify the existence of a bit line or word line ordering mismatch but does not identify the location of this ordering mismatch. A circuit designer may thus be forced to manually identify the location of the mismatch in the layout, which is very time consuming and costly.

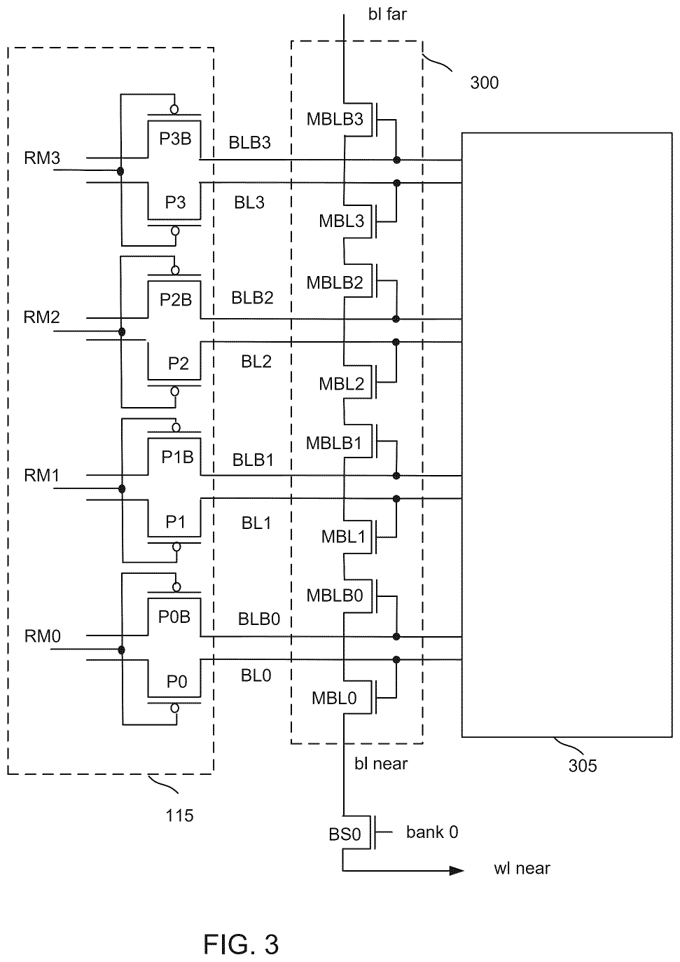

To solve the word line and bit line order mismatch issue, stacked transistors are added that break the symmetry by introducing an asymmetry. An LVS check may then readily identify not only the presence of an order mismatch but also its location. In this fashion, a designer does not need to manually identify the location of the mismatch, which saves a significant amount of time and cost. A bit line transistor stack is used for verifying the bit line order. Similarly, a word line transistor stack is used for verifying the word line order. An example bit line transistor stack 300 is shown in FIG. 3 for the bit lines addressed by the column multiplexer 115 of memory 100. Since the column multiplexer 115 performs the column selection for a single GIO signal, the bit line transistor stack 300 addresses the order of just the bit lines for the four corresponding columns. However, it will be appreciated that the bit line transistor stack 300 is readily extended to couple to all the remaining bit lines in a bank 305 as will be explained further herein. The bit line transistor stack 300 includes an NMOS bit line transistor for each bit line in the GIO. For example, the bit line transistor stack 300 begins with a bit line transistor MBL0 having a first drain/source terminal coupled to a bit line near (bl near) node. The bl near node is the beginning node for the bit line transistor stack 300 and couples to a drain/source terminal of a bank selection transistor BS0 (assuming that the bank 305 is a zeroth bank for the corresponding memory). A bank selection signal (bank 0) for the zeroth bank drives the gate of the bank selection transistor BS0. As used herein, a “drain/source terminal” refers to either a drain or a source of a transistor. In that regard, note that a current direction needs not be defined for the bit line transistor stack 300 since the bit line transistor stack 300 does not have a function during operation of the corresponding memory but instead is introduced for verification of the bit line order.

Each bit line transistor in the bit line transistor stack 300 has its gate coupled to the corresponding bit line and coupled to a source of the corresponding column multiplexer transistor. For example, the gate of the bit line transistor MBL0 couples to the zeroth bit line BL0 and to the source of the column multiplexer transistor P0. Each successive bit line transistor in the bit line transistor stack 300 has a first source/drain terminal coupled to a second source/drain terminal of the preceding bit line transistor in the transistor stack 300. For example, a second source/drain terminal of the bit line transistor MBL0 couples to a first drain/source terminal of a bit line transistor MBLB0 having a gate coupled to the complement zeroth bit line BLB0 and to the source of the column multiplexer transistor P0B. Similarly, a second source/drain terminal of the bit line transistor MBLB0 couples to a first drain/source terminal of a bit line transistor MBL1 having a gate coupled to the first bit line BL1 and to the source of the column multiplexer transistor P1. A second drain/source terminal of the bit line transistor MBL1 couples to a first drain/source terminal of a bit line transistor MBLB1 having a gate coupled to the complement first bit line BLB1 and to the source of the column multiplexer transistor P1B. In the same fashion, a second drain/source terminal of the bit line transistor MBLB1 couples to a first drain/source terminal of a bit line transistor MBL2 having a gate coupled to the second bit line BL2 and coupled to the source of the column multiplexer transistor P2. A second drain/source terminal of the bit line transistor MBL2 couples to a first terminal of a bit line transistor MBLB2 having a gate coupled to the complement second bit line BLB2 and coupled to the source of the column multiplexer transistor P2B. A second drain/source terminal of the bit line transistor MBLB2 couples to a first drain/source terminal of a bit line transistor MBL3 having a gate coupled to the third bit line BLB3 and coupled to the source of the column multiplexer transistor P3. A second drain/source terminal of the bit line transistor MBL3 couples to a first drain/source terminal of a bit line transistor MBLB3 having a gate coupled to the complement third bit line BLB3 and coupled to the source of the column multiplexer transistor P3B. Finally, the second drain/source terminal of the bit line transistor MBLB3 couples to a bit line far (bl far) node to complete the transistor stack 300. The bit line transistor stack 300 may instead be formed using PMOS transistors in alternative implementations.

It may be seen that additional bit line transistor stacks for additional GIOs may be arranged in series corresponding to the GIO order. In the bit line transistor stack series, each successive bit line transistor stack has its bit line near node coupled to the bit line far node of the preceding transistor stack. Regardless of the number of GIOs (and thus the same number of transistor stacks), each bit line for a GIO couples to the gate of a corresponding transistor in the corresponding bit line transistor stack. The bit line transistors in each bit line transistor stack are coupled from one drain/source terminal to another according to their bit line order. It may thus be appreciated that the symmetry with respect to the bit lines discussed with regard to FIGS. 1 and 2 is broken by the addition of bit line transistor stacks such as the bit line transistor stack 300. For example, suppose that the column address signals rm0 and rm1 have been exchanged due to a memory layout tiler software bug. An LVS check of the resulting GDS layout will readily observe that the schematic requires the first drain/source terminal of the transistor MBL0 to be coupled to the bit line near node and that the gate of the transistor MBL0 should couple to the zeroth bit line BL0 and to the source of the column multiplexer transistor P0. But due to the bit line order mismatch resulting from the exchange of the address signals rm0 and rm1, bit line 0 now couples to the gate of the transistor MBL1 instead of to the gate of transistor MBL0. Thus, an LVS check may readily identify the location of the bit line order mismatch. In this fashion, the memory layout tiler software is readily fixed to produce the correct GDS layout before tapeout, resulting in the memory built-in self-test operating as desired.

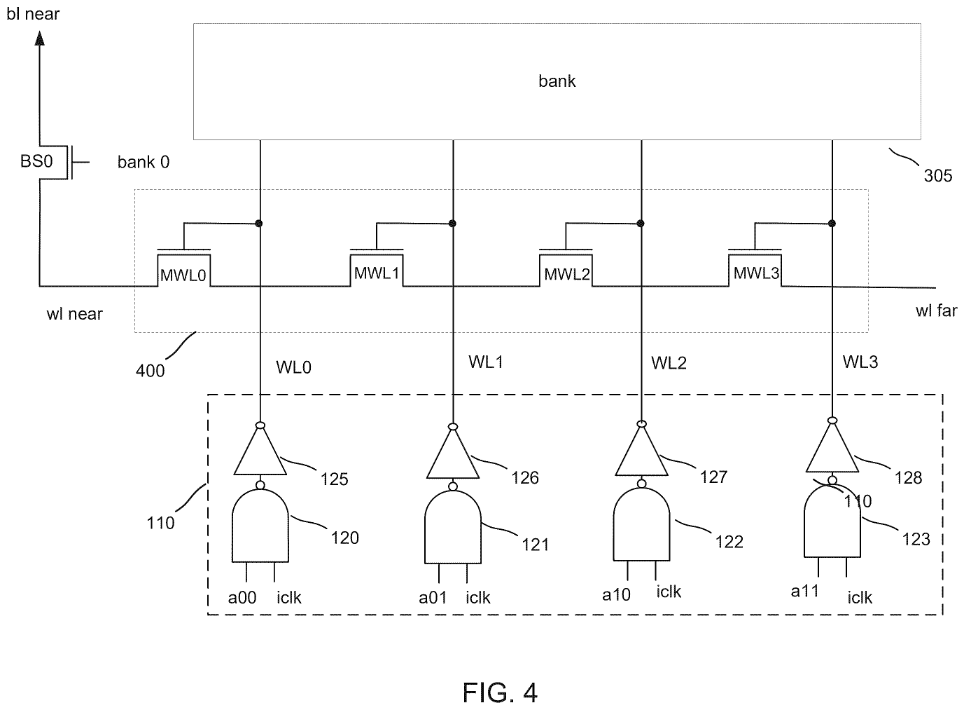

As shown in FIG. 4, an example word line transistor stack 400 for the word lines addressed by the portion 110 of the row decoder for memory 100. The word line transistor stack 400 thus addresses the order of the word lines for the four corresponding rows, ranging from the zeroth word line WL0 to the third word line WL3. However, it will be appreciated that the word line transistor stack 400 is readily extended to cover all the remaining word lines in the bank 305 as will be explained further herein. The word line transistor stack 400 extends from a word line near (wl near) node at a second drain/source terminal of the bank select transistor BS0 to a word line far (wl far) node and has one NMOS transistor for each word line. There is thus a zeroth word line transistor MWL0 having a first drain/source terminal coupled to the word line near node and having a gate coupled to the zeroth word line WL0 and to an output terminal of the inverter 125. More generally, the zeroth word line transistor MWL0 has a gate coupled to the output terminal of whatever is the final logic gate in the row decoder 400 that drives the zeroth word line WL0. A second drain/source terminal of the transistor MWL0 couples to a first drain/source terminal of a first word line transistor MWL1 having a gate coupled to the first word line WL1 and to the output terminal of the inverter 126. Similarly, a second drain/source terminal of the transistor MWL1 couples to a first drain/source terminal of a second word line transistor MWL2 having a gate coupled to the second word line WL2 and to the output terminal of the inverter 127. In addition, a second drain/source terminal of the transistor MWL2 couples to a first drain/source terminal of a third word line transistor MWL3 having a gate coupled to the third word line WL3 and to the output terminal of the inverter 128. Finally, a second drain/source terminal of the transistor MWL3 couples to the word line far node to complete the word line transistor stack 400. Additional word line transistor stacks may be serially arranged such that the word line near node of a successive stack in the series couples to the word line far node of the preceding stack. PMOS transistors may instead be used to form the word line transistor stack in alternative implementations.

The transistors in each word line transistor stack 400 are coupled from one drain/source terminal to another according to their word line order. It may thus be appreciated that the symmetry with respect to the word lines discussed with regard to FIGS. 1 and 2 is broken by the addition of word line transistor stacks such as the word line transistor stack 400. For example, suppose that the pre-decoded address signals a00 and a01 have been exchanged due to a memory layout software bug or error. An LVS check of the resulting GDS layout will readily observe that the schematic requires the first drain/source terminal of the transistor MWL0 to be coupled to the word line near node and that the gate of the transistor MWL0 should couple to the zeroth word line BL0. But due to the bit line order mismatch resulting from the exchange of the pre-decoded address signals a00 and a01, word line 0 now couples to the gate of the transistor MWL1 instead of to the gate of transistor MWL0. Thus, an LVS check may readily identify the location of the word line order mismatch. In this fashion, the memory layout tiler software error is readily fixed to produce the correct GDS layout before tapeout, resulting in robust performance of the memory built-in self-test.

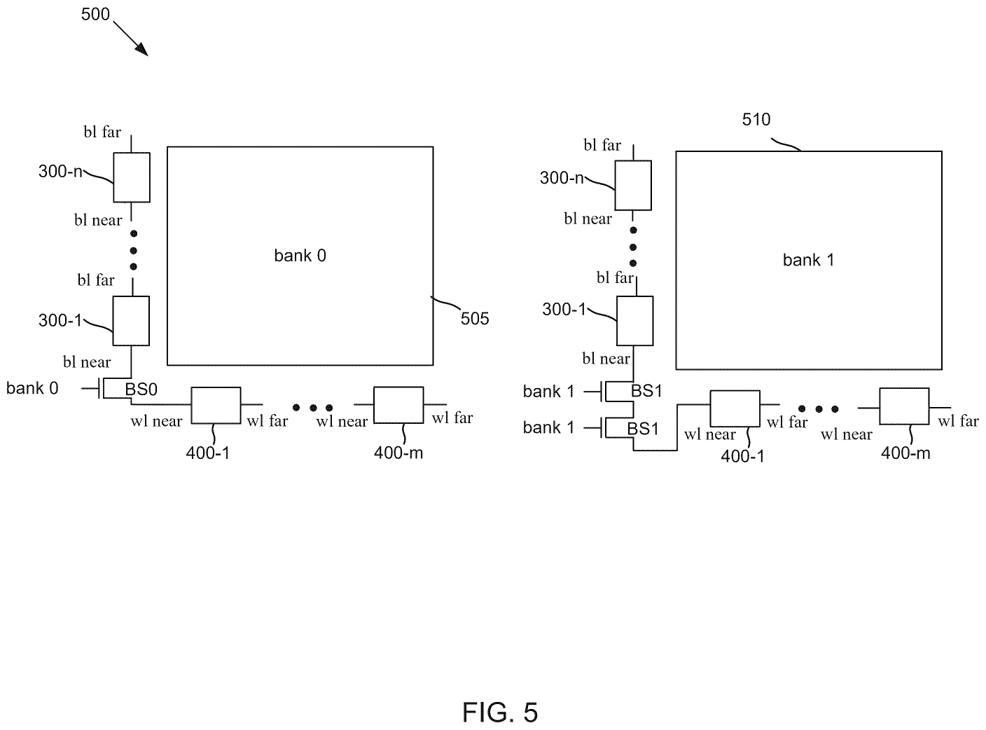

As noted earlier, the bitcells for a memory are typically arranged into multiple banks. If only one bank selection transistor analogous to the transistor BS0 were used to join between the bit line transistor stack 300 and the word line transistor 400, note that each bank would be symmetric with each other. To break this symmetry, each bank may receive a different number of bank selection transistors. An example memory 500 is shown in FIG. 5. Memory 500 includes a zeroth bank 505 and a first bank 510. Each of the zeroth bank 505 and the first bank 510 is accessed during a read or write operation by a plurality of column multiplexers (not illustrated) with each column multiplexer being analogous or equivalent to the column multiplexer 115 for each GIO signal. Should there be a plurality of n GIO signals (n being a plural integer), there would thus be n column multiplexers. The bit lines for each GIO signal are coupled to a bit line transistor stack analogous to the bit line transistor stack 300. Since there are n GIO signals, there are n bit line transistor stacks. For the zeroth bank 505, there is thus a first bit line transistor stack 300-1 for a first GIO, a second bit line transistor stack (not illustrated) for a second GIO, and so on such that there is an nth bit line transistor stack 300-n for the nth GIO. Each of these bit line transistor stacks is coupled between a corresponding bit line near node and a bit line far node. The bit line far node for a preceding one of the bit line transistors stacks is also the bit line near node for the successive one of the bit line transistor stacks. For example, a bit line far node (bl far) for the first transistor stack 300-1 is also a bit line near node (bl near) for a second transistor stack (not illustrated). The first bank 510 has an analogous series of bit line transistor stacks beginning with a first bit line transistor stack 300-1 and ending with the nth bit line transistor stack 300-n.

Each of the zeroth bank 505 and the first bank 510 is also accessed during a read or write operation by a plurality of row decoder portions (not illustrated) with each row decoder portion being analogous or equivalent to the row decoder portion 110. The number of row decoder portions may depend upon the number of pre-decoded row address signals. Each row decoder portion selects from a corresponding group of word lines that are coupled to a word line transistor stack analogous to the word line transistor stack 400. In one implementation, there are m row decoder portions (m being a plural integer) such that there are m word line transistor stacks ranging from a first word line transistor stack 400-1 to an mth word line transistor stack 400-m for each bank. Each of these bit line transistor stacks is coupled between a corresponding word line near node and a word line far node. The word line far node for a preceding one of the word line transistors stacks in the series is also the word line near node for the successive one of the word line transistor stacks. For example, a word line far node (wl far) for the first word line transistor stack 400-1 for the zeroth bank 505 is also a bit line near node (bl near) for a second word line transistor stack (not illustrated). The first bank 510 has an analogous series of bit line transistor stacks beginning with the first word line transistor stack 400-1 and ending with the mth word line transistor stack 400-m.

The single bank selection transistor bs0 couples between the first bit line transistor stack 300-1 and the first word line transistor stack 400-1 for the zeroth bank 505. A zeroth bank selection signal (bank 0) that couples to the gate of the bank selection transistor bs0 is asserted during a read or write operation to the zeroth bank 505. To distinguish the first bank 510 from the zeroth bank 505, two bank selection transistors bs1 couple between the transistor stack 300-1 and the first word line transistor stack 400-1 for the first bank 510. A first bank selection signal (bank 1) that couples to the gate of each of the bank selection transistors bs1 is asserted during a read or write operation to the first bank 510. More generally, the memory 500 may have more than two banks, with each bank being identified by a unique number of bank selection transistors.

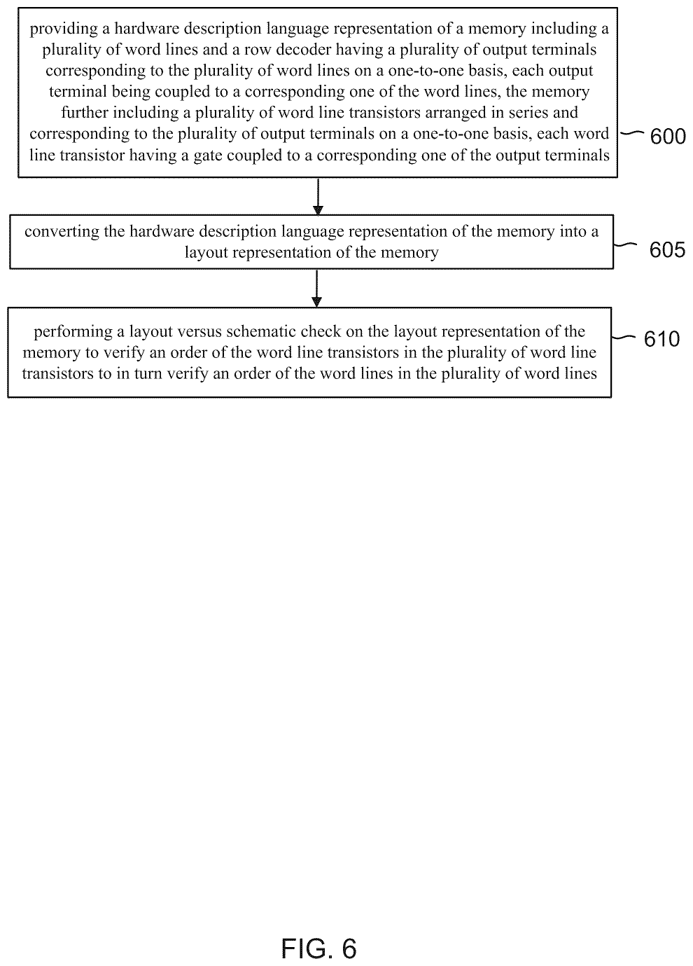

A method of verifying a word line order will now be discussed with respect to the flowchart of FIG. 6. The method includes an act 600 of providing a hardware description language representation of a memory including a plurality of word lines and a row decoder having a plurality of output terminals corresponding to the plurality of word lines on a one-to-one basis, each output terminal being coupled to a corresponding one of the word lines, the memory further including a plurality of word line transistors arranged in series and corresponding to the plurality of output terminals on a one-to-one basis, each word line transistor having a gate coupled to a corresponding one of the output terminals. The development of a hardware description language representation of any of the memories discussed with respect to FIGS. 4 and 5 is an example of act 600. The method also includes an act 605 of converting the hardware description language representation of the memory into a layout representation of the memory. The development of a layout representation of any of the memories discussed with respect to FIGS. 4 and 5 is an example of act 605. Finally, the method includes an act 610 of performing a layout versus schematic check on the layout representation of the memory to verify an order of the word line transistors in the plurality of word line transistors to in turn verify an order of the word lines in the plurality of word lines. The verification of the word line order as discussed with respect to FIG. 4 is an example of act 610.

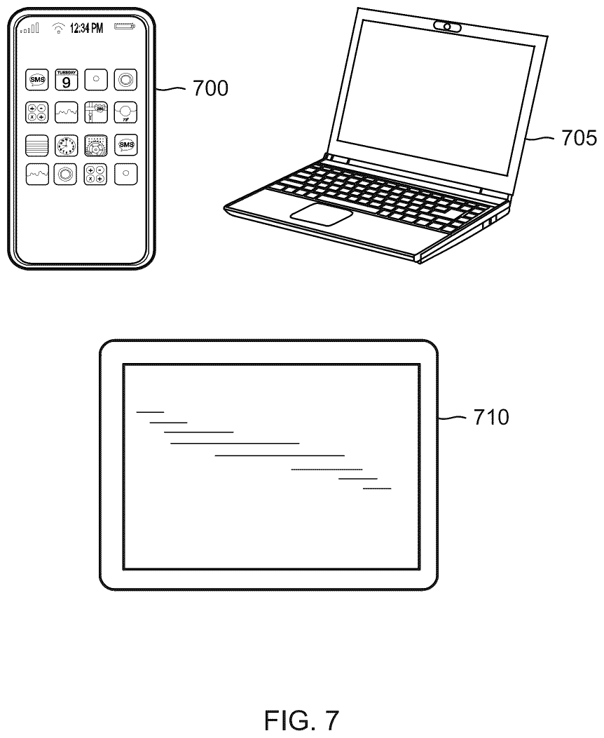

A memory configured for bit line and word line order verification as disclosed herein may be incorporated in a wide variety of electronic systems. For example, as shown in FIG. 7, a cellular telephone 700, a laptop computer 705, and a tablet 710 may all include a memory in accordance with the disclosure. Other exemplary electronic systems such as a video player, a communication device, and a personal computer may also be configured with a memory constructed in accordance with the disclosure.

Some example implementations are described by the following numbered clauses:
Clause 1. A memory comprising:
   a first word line;
   a second word line;
   a row decoder including a first logic gate having a first output terminal coupled to the first word line and a second logic gate having a second output terminal coupled to the second word line;
   an at least one bank selection transistor having a gate coupled to a node for bank selection signal;
   a first word line transistor having a first drain/source terminal coupled to the at least one bank selection transistor and having a gate coupled to the first output terminal; and
   a second word line transistor having a first drain/source terminal coupled to a second drain/source terminal of the first word line transistor and having a gate coupled to the second output terminal.
Clause 2. The memory of clause 1, wherein the first logic gate comprises a first inverter and the second logic gate comprises a second inverter.
Clause 3. The memory of any of clauses 1-2, further comprising:
   a first bit line;
   a second bit line;
   a column multiplexer including a first column multiplexer transistor having a source coupled to the first bit line and including a second column multiplexer transistor having a source coupled to the second bit line, wherein a node for a column address signal couples to gate of the first column multiplexer transistor and couples to a gate of the second column multiplexer transistor;
   a first bit line transistor having a first source/drain terminal coupled to the at least one bank selection transistor and having a gate coupled to the source of the first column multiplexer transistor; and
   a second bit line transistor having a first source/drain terminal coupled to a second source/drain terminal of the first bit line transistor and having a gate coupled to the source of the second column multiplexer transistor.
Clause 4. The memory of clause 3, wherein the at least one bank selection transistor comprises a single bank selection transistor.
Clause 5. The memory of clause 3, wherein the at least one bank selection transistor comprises a plurality of bank selection transistors.
Clause 6. A memory comprising:
   a plurality of bitcells arranged into a plurality of rows of bitcells ranging from a first row of bitcells to a last row of bitcells;
   a plurality of word lines ranging from a first word line to a last word line, each word line being arranged to couple to a corresponding row of bitcells such that the first word line is coupled to the first row of bitcells, a second word line is coupled to a second row of bitcells, and so on such that the last word line is coupled to the last row of bitcells;
   a row decoder having a plurality of output terminals ranging from a first output terminal to a last output terminal arranged corresponding to the plurality of word lines such that the first output terminal is coupled to the first word line, a second output terminal is coupled to the second word line, and so on such that the last output terminal is coupled to the last word line; and
   a plurality of word line transistors coupled in series and ranging from a first word line transistor to a last word line transistor, the plurality of word line transistors being arranged such that a gate of the first word line transistor is coupled to the first output terminal, a gate of a second word line transistor is coupled to the second output terminal; and so on such that a gate of the last word line transistor is coupled to the last output terminal.
Clause 7. The memory of clause 6, further comprising:
   a first node; and
   a second node, wherein the plurality of word line transistors are arranged in series between the first node and the second node such that the first word line transistor has a first drain/source terminal coupled to the first node and has a second drain/source terminal coupled to a first drain/source terminal of the second word line transistor, and so on such that the last word line transistor has a first drain/source terminal coupled to a second drain/source terminal of a next-to-last word line transistor and has a second drain/source terminal coupled to the second node.
Clause 8. The memory of clause 7, wherein the plurality of bitcells is also arranged into a plurality of columns of bitcells ranging from a first column of bitcells to a last column of bitcells.
Clause 9. The memory of clause 8, further comprising:
   a plurality of bit lines ranging from a first bit line to a last bit line, the plurality of bit lines being arranged to form a plurality of bit line pairs ranging from a first bit line pair to a last bit line pair, each bit line pair being arranged to couple to a corresponding column of bitcells such that the first bit line pair is coupled to the first column of bitcells, a second bit line pair is coupled to a second column of bitcells, and so on such that the last bit line pair is coupled to the last column of bitcells.
Clause 10. The memory of clause 9, further comprising:
   a column multiplexer having a plurality of output terminals arranged corresponding to the plurality of bit lines such that a first output terminal of the column multiplexer is coupled to the first bit line, a second output terminal of the column multiplexer is coupled to a second bit line, and so on such that a last output terminal of the column multiplexer is coupled to the last bit line; and
   a plurality of bit line transistors coupled in series from a first bit line transistor to a last bit line transistor, the plurality of bit line transistors being arranged such that a gate of the first bit line transistor is coupled to the first output terminal of the column multiplexer, a gate of a second bit line transistor is coupled to the second output terminal of the column multiplexer, and so on such that a gate of the last bit line transistor is coupled to the last output terminal of the column multiplexer.
Clause 11. The memory of clause 10, further comprising:
   a third node; and
   a fourth node, wherein the plurality of bit line transistors are arranged in series between the third node and the fourth node such that the first bit line transistor has a first drain/source terminal coupled to the third node and has a second drain/source terminal coupled to a first drain/source terminal of the second bit line transistor, and so on such that the last bit line transistor has a first drain/source terminal coupled to a second drain/source terminal of a next-to-last bit line transistor and has a second drain/source terminal coupled to the fourth node.
Clause 12. The memory of any of clauses 7-11, wherein the plurality of bitcells is included within a first bank, the memory further comprising:
   a first bank select transistor having a first drain/source terminal coupled to the first node and having a gate coupled to a node for a first bank select signal.
Clause 13. The memory of any of clauses 6-12, wherein the memory is included within a cellular telephone.
Clause 14. A method of verifying a word line order comprising:
   providing a hardware description language representation of a memory including a plurality of word lines and a row decoder having a plurality of output terminals corresponding to the plurality of word lines on a one-to-one basis, each output terminal being coupled to a corresponding one of the word lines, the memory further including a plurality of word line transistors arranged in series and corresponding to the plurality of output terminals on a one-to-one basis, each word line transistor having a gate coupled to a corresponding one of the output terminals;
   converting the hardware description language representation of the memory into a layout representation of the memory; and
   performing a layout versus schematic check on the layout representation of the memory to verify an order of the word line transistors in the plurality of word line transistors to in turn verify an order of the word lines in the plurality of word lines.
Clause 15. The method of clause 14, wherein the hardware description language representation of the memory comprises a Memory and SMS Interface (MASIS) representation of the memory.
Clause 16. The method of any of clauses 14-15, wherein the layout representation of the memory comprises a graphic design system (GDS) representation of the memory.
Clause 17. The method of any of clauses 14-16, wherein the hardware description language representation of the memory further includes a plurality of bit lines and a column multiplexer having a plurality of output terminals corresponding to the plurality of bit lines on a one-to-one basis, each output terminal of the column multiplexer being coupled to a corresponding one of the bit lines, the memory further including a plurality of bit line transistors arranged in series and corresponding to the plurality of output terminals of the column multiplexer on a one-to-one basis, each bit line transistor having a gate coupled to a corresponding one of the output terminals of the column multiplexer, and wherein performing the layout versus schematic check on the layout representation of the memory verifies an order of the bit line transistors in the plurality of bit line transistors to in turn verify an order of the bit lines in the plurality of bit lines.
Clause 18. The method of clause 17, further comprising:
   detecting a mismatch in the order of the bit lines responsive to performing the layout versus schematic check.
Clause 19. The method of any of clauses 14-18, wherein the hardware description language representation of the memory further includes a bank and a plurality of bank select transistors coupled to a first one of the word line transistors, and wherein performing the layout versus schematic check on the layout representation of the memory to verify the order of the word line transistors further includes counting the bank select transistors to identify the bank.
Clause 20. The method of any of clauses 14-19, further comprising:
   detecting a mismatch in the order of the word lines responsive to performing the layout versus schematic check.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory comprising:
a first word line;
a second word line;
a row decoder including a first logic gate having a first output terminal coupled to the first word line and a second logic gate having a second output terminal coupled to the second word line;
an at least one bank selection transistor having a gate coupled to a node for bank selection signal;
a first word line transistor having a first drain/source terminal coupled to the at least one bank selection transistor and having a gate coupled to the first output terminal; and
a second word line transistor having a first drain/source terminal coupled to a second drain/source terminal of the first word line transistor and having a gate coupled to the second output terminal.

2. The memory of claim 1, wherein the first logic gate comprises a first inverter and the second logic gate comprises a second inverter.

3. The memory of claim 1, further comprising:
a first bit line;
a second bit line;
a column multiplexer including a first column multiplexer transistor having a source coupled to the first bit line and including a second column multiplexer transistor having a source coupled to the second bit line, wherein a node for a column address signal couples to gate of the first column multiplexer transistor and couples to a gate of the second column multiplexer transistor;
a first bit line transistor having a first source/drain terminal coupled to the at least one bank selection transistor and having a gate coupled to the source of the first column multiplexer transistor; and
a second bit line transistor having a first source/drain terminal coupled to a second source/drain terminal of the first bit line transistor and having a gate coupled to the source of the second column multiplexer transistor.

4. The memory of claim 3, wherein the at least one bank selection transistor comprises a single bank selection transistor.

5. The memory of claim 3, wherein the at least one bank selection transistor comprises a plurality of bank selection transistors.

6. A memory comprising:
a plurality of bitcells arranged into a plurality of rows of bitcells ranging from a first row of bitcells to a last row of bitcells;
a plurality of word lines ranging from a first word line to a last word line, each word line being arranged to couple to a corresponding row of bitcells such that the first word line is coupled to the first row of bitcells, a second word line is coupled to a second row of bitcells, and so on such that the last word line is coupled to the last row of bitcells;
a row decoder having a plurality of output terminals ranging from a first output terminal to a last output terminal arranged corresponding to the plurality of word lines such that the first output terminal is coupled to the first word line, a second output terminal is coupled to the second word line, and so on such that the last output terminal is coupled to the last word line; and
a plurality of word line transistors coupled in series and ranging from a first word line transistor to a last word line transistor, the plurality of word line transistors being arranged such that a gate of the first word line transistor is coupled to the first output terminal, a gate of a second word line transistor is coupled to the second output terminal; and so on such that a gate of the last word line transistor is coupled to the last output terminal.

7. The memory of claim 6, further comprising:
a first node; and
a second node, wherein the plurality of word line transistors are arranged in series between the first node and the second node such that the first word line transistor has a first drain/source terminal coupled to the first node and has a second drain/source terminal coupled to a first drain/source terminal of the second word line transistor, and so on such that the last word line transistor has a first drain/source terminal coupled to a second drain/source terminal of a next-to-last word line transistor and has a second drain/source terminal coupled to the second node.

8. The memory of claim 7, wherein the plurality of bitcells is also arranged into a plurality of columns of bitcells ranging from a first column of bitcells to a last column of bitcells.

9. The memory of claim 8, further comprising:
a plurality of bit lines ranging from a first bit line to a last bit line, the plurality of bit lines being arranged to form a plurality of bit line pairs ranging from a first bit line pair to a last bit line pair, each bit line pair being arranged to couple to a corresponding column of bitcells such that the first bit line pair is coupled to the first column of bitcells, a second bit line pair is coupled to a second column of bitcells, and so on such that the last bit line pair is coupled to the last column of bitcells.

10. The memory of claim 9, further comprising:
a column multiplexer having a plurality of output terminals arranged corresponding to the plurality of bit lines such that a first output terminal of the column multiplexer is coupled to the first bit line, a second output terminal of the column multiplexer is coupled to a second bit line, and so on such that a last output terminal of the column multiplexer is coupled to the last bit line; and
a plurality of bit line transistors coupled in series from a first bit line transistor to a last bit line transistor, the plurality of bit line transistors being arranged such that a gate of the first bit line transistor is coupled to the first output terminal of the column multiplexer, a gate of a second bit line transistor is coupled to the second output terminal of the column multiplexer, and so on such that a gate of the last bit line transistor is coupled to the last output terminal of the column multiplexer.

11. The memory of claim 10, further comprising:
a third node; and
a fourth node, wherein the plurality of bit line transistors are arranged in series between the third node and the fourth node such that the first bit line transistor has a first drain/source terminal coupled to the third node and has a second drain/source terminal coupled to a first drain/source terminal of the second bit line transistor, and so on such that the last bit line transistor has a first drain/source terminal coupled to a second drain/source terminal of a next-to-last bit line transistor and has a second drain/source terminal coupled to the fourth node.

12. The memory of claim 7, wherein the plurality of bitcells is included within a first bank, the memory further comprising:
a first bank select transistor having a first drain/source terminal coupled to the first node and having a gate coupled to a node for a first bank select signal.

13. The memory of claim 6, wherein the memory is included within a cellular telephone.

14. A memory, comprising:
a first bit line;
a second bit line;
an at least one bank selection transistor having a gate coupled to a node for bank selection signal;
a column multiplexer including a first column multiplexer transistor having a source coupled to the first bit line and including a second column multiplexer transistor having a source coupled to the second bit line, wherein a node for a first column address signal couples to gate of the first column multiplexer transistor and couples to a gate of the second column multiplexer transistor;
a first bit line transistor having a first source/drain terminal coupled to the at least one bank selection transistor and having a gate coupled to the source of the first column multiplexer transistor; and
a second bit line transistor having a first source/drain terminal coupled to a second source/drain terminal of the first bit line transistor and having a gate coupled to the source of the second column multiplexer transistor.

15. The memory of claim 14, wherein the at least one bank selection transistor comprises a single bank selection transistor.

16. The memory of claim 14, wherein the at least one bank selection transistor comprises a plurality of bank selection transistors.

17. The memory of claim 14, further comprising:
a third bit line;
a fourth bit line, wherein the column multiplexer further includes a third column multiplexer transistor having a source coupled to the third bit line and includes a fourth column multiplexer transistor having a source coupled to the fourth bit line, and wherein a node for a second column address signal couples to gate of the third column multiplexer transistor and couples to a gate of the fourth column multiplexer transistor;
a third bit line transistor having a first source/drain terminal coupled to a second source/drain terminal of the second bit line transistor and having a gate coupled to the source of the third column multiplexer transistor; and
a fourth bit line transistor having a first source/drain terminal coupled to a second source/drain terminal of the third bit line transistor and having a gate coupled to the source of the fourth column multiplexer transistor.

18. The memory of claim 14, wherein the first bit line transistor and the second bit line transistor each comprises an n-type metal-oxide semiconductor (NMOS) transistor.

19. The memory of claim 14, wherein the first column multiplexer transistor and the second column multiplexer transistor each comprises a p-type metal-oxide semiconductor (PMOS) transistor.

20. The memory of claim 14, wherein the at least one bank selection transistor comprises an NMOS transistor.
